(19) United States
(12) Patent Application Publication
(10) Pub. No.: US 2024/0074326 A1
(43) Pub. Date: Feb. 29, 2024

(54) MAGNETORESISTANCE EFFECT ELEMENT AND MAGNETIC MEMORY

(71) Applicant: TDK CORPORATION, Tokyo (JP)

(72) Inventors: Yugo ISHITANI, Tokyo (JP); Tomoyuki SASAKI, Tokyo (JP)

(73) Assignee: TDK CORPORATION, Tokyo (JP)

(21) Appl. No.: 18/280,321

(22) PCT Filed: Mar. 12, 2021
(86) PCT No.: PCT/JP2021/010001

§ 371 Date: Sep. 5, 2023

(51) Int. Cl. H10N 50/80; H10B 61/00; H10N 50/01; H10N 50/20; H10N 50/85

(52) U.S. Cl. CPC H10N 50/80; H10B 61/00; H10N 50/01; H10N 50/20; H10N 50/85

(57) ABSTRACT

A magnetoresistance effect element includes a laminated body having a first ferromagnetic layer, a second ferromagnetic layer, and a nonmagnetic layer located between the first ferromagnetic layer and the second ferromagnetic layer, a first wiring connected to the laminated body, a sidewall insulating layer configured to cover at least a part of a side surface of the laminated body, a first electrode connected to a side of the laminated body opposite to the first wiring, and a second electrode and a third electrode provided on both sides of the laminated body with the sidewall insulating layer sandwiched therebetween, sandwiching the laminated body, and connected to the first wiring.

### TECHNICAL FIELD

The present invention relates to a magnetoresistance effect element and a magnetic memory.

### BACKGROUND ART

A giant magnetoresistance (GMR) element constituted by a multi-layer film of a ferromagnetic layer and a nonmagnetic layer, and a tunnel magnetoresistance (TMR) element using an insulating layer (a tunnel barrier layer, a barrier layer) in a nonmagnetic layer are known as a magnetoresistance effect element. The magnetoresistance effect element can be applied to a magnetic sensor, high frequency parts, a magnetic head and a non-volatile random access memory (MRAM).

The MRAM is a storage element in which magnetoresistance effect elements are integrated. The MRAM reads data using characteristics that a resistance of the magnetoresistance effect element is changed when the orientation of magnetization between two ferromagnetic layers that sandwich a nonmagnetic layer in the magnetoresistance effect element is changed. The orientation of the magnetization of the ferromagnetic layer is controlled using, for example, a magnetic field generated by current. In addition, for example, the orientation of the magnetization of the ferromagnetic layer is controlled using a spin transfer torque (STT) generated by flowing current in a laminating direction of the magnetoresistance effect element.

When the orientation of the magnetization of the ferromagnetic layer is rewritten using the STT, the current flows in the laminating direction of the magnetoresistance effect element. The writing current causes characteristics degradation of the magnetoresistance effect element.

In recent years, attention has focused on a method that does not require current to flow in the laminating direction of the magnetoresistance effect element during writing. One of the methods is a writing method using a spin orbit torque (SOT). The SOT is induced by spin current generated by a spin-orbit interaction or Rashba effect in an interface between different materials. The current configured to induce the SOT into the magnetoresistance effect element flows in a direction crossing a laminating direction of the magnetoresistance effect element. That is, there is no need to flow the current in the laminating direction of the magnetoresistance effect element, and a longer life of the magnetoresistance effect element is expected.

### CITATION LIST

### Patent Document

[Patent Document 1]
Japanese Patent No. 6426330

### Summary of Invention

### Technical Problem

The spin orbit torque wiring has high resistance and tends to generate heat when writing current is applied. For this reason, the length of the spin orbit torque wiring tends to be shortened. However, due to the relation of process accuracy, it was difficult to fabricate the electrodes that conduct the spin orbit torque wiring sufficiently close to each other, and it was difficult to shorten the length of the spin orbit torque wiring sufficiently.

In consideration of the above-mentioned circumstances, the present invention is directed to providing a magnetoresistance effect element and a magnetic memory that are capable of reducing malfunctions due to heat generation of spin orbit torque wiring.

### Solution to Problem

In order to solve the aforementioned problems, the present invention provides the following means.

(1) A magnetoresistance effect element according to a first aspect includes: a laminated body having a first ferromagnetic layer, a second ferromagnetic layer, and a nonmagnetic layer located between the first ferromagnetic layer and the second ferromagnetic layer; a first wiring connected to the laminated body; a sidewall insulating layer configured to cover at least a part of a side surface of the laminated body; a first electrode connected to a side of the laminated body opposite to the first wiring; and a second electrode and a third electrode provided on both sides of the laminated body with the sidewall insulating layer sandwiched therebetween, sandwiching the laminated body, and connected to the first wiring.

(2) In the magnetoresistance effect element according to the above-mentioned aspect, the laminated body may be located on the first electrode, and a circumference of the first electrode may be equal to or greater than a maximum circumference of the laminated body.

(3) In the magnetoresistance effect element according to the above-mentioned aspect, the first electrode and the sidewall insulating layer may be in contact with each other.

(4) In the magnetoresistance effect element according to the above-mentioned aspect, the sidewall insulating layer may have a first portion in contact with the side surface of the laminated body, and a second portion in contact with the first electrode; and the first portion and the second portion may be inclined with respect to a laminating direction of the laminated body and a surface perpendicular to the laminating direction, respectively.

(5) In the magnetoresistance effect element according to the above-mentioned aspect, the sidewall insulating layer may have a first portion in contact with the side surface of the laminated body, and a second portion in contact with the first electrode; and an inclination angle of a tangential plane in contact with the sidewall insulating layer with respect to a laminating direction of the laminated body is changed continuously from the first portion to the second portion.

(6) In the magnetoresistance effect element according to the above-mentioned aspect, the laminated body may be located on the first electrode, the sidewall insulating layer may have a first portion in contact with the side surface of the laminated body, and a second portion in contact with the first electrode, and at least a part of the second portion may be located below the first surface of the first electrode on the side of the laminated body.

(7) In the magnetoresistance effect element according to the above-mentioned aspect, an average thickness of the sidewall insulating layer may be greater than an average thickness of the nonmagnetic layer.

(8) The magnetoresistance effect element according to the above-mentioned aspect may further include a diffusion prevention layer, and the diffusion prevention layer may be an inner portion of at least one of the second electrode and the third electrode or an interface with the sidewall insulating layer.

(9) In the magnetoresistance effect element according to the above-mentioned aspect, the diffusion prevention layer may contain a metal having a specific weight equal to or greater than that of yttrium as a main component.

(10) In the magnetoresistance effect element according to the above-mentioned aspect, at least one of the second electrode and the third electrode may contain a metal having a specific weight equal to or greater than yttrium as a main component.

(11) In the magnetoresistance effect element according to the above-mentioned aspect, the laminated body may further include a spin conduction layer or a spin generation layer connected to the first wiring, the spin conduction layer may be a metal or a semiconductor containing any one element selected from the group consisting of Cu, Ag, Al, Mg, Zn, Si, Ge, and C, and the spin generation layer may contain a metal having a specific weight equal to or greater than that of yttrium as a main component.

(12) In the magnetoresistance effect element according to the above-mentioned aspect, the sidewall insulating layer may be oxide, and the spin conduction layer or the spin generation layer may be in contact with the sidewall insulating layer.

(13) The magnetoresistance effect element according to the above-mentioned aspect may further include a first via wiring connected to the second electrode, and a second via wiring connected to the third electrode.

(14) In the magnetoresistance effect element according to the above-mentioned aspect, the first via wiring and the second via wiring may extend in a direction different from a laminating direction of the laminated body with reference to the laminated body.

(15) In the magnetoresistance effect element according to the above-mentioned aspect, an inclination angle of a first side surface of the laminated body with respect to the laminating direction at a first cut section cut along a cross section in a first direction from the second electrode toward the third electrode passing through a center when the laminated body is seen in a laminating direction of the laminated body may be greater than an inclination angle of a second side surface of the laminated body with respect to the laminating direction in a second cut section passing through the center and perpendicular to the first direction.

(16) In the magnetoresistance effect element according to the above-mentioned aspect, the second electrode and the third electrode may be magnetic bodies having a magnetization easy axis from the second electrode toward the third electrode in the first direction, and the magnetization easy axis of the first ferromagnetic layer and the second ferromagnetic layer may be in the laminating direction of the laminated body.

(17) A magnetic memory according to a second aspect includes the plurality of magnetoresistance effect elements according to the above-mentioned aspect.

### Advantageous Effects of Invention

According to the present invention, the magnetoresistance effect element and the magnetic memory can reduce malfunctions due to heat generation of the spin orbit torque wiring.

### BRIEF DESCRIPTION OF DRAWINGS

FIG. 1 is a circuit diagram of a magnetic memory according to a first embodiment.

FIG. 2 is a cross-sectional view of a feature portion of the magnetic memory according to the first embodiment.

FIG. 3 is a cross-sectional view of a magnetoresistance effect element according to the first embodiment.

FIG. 4 is another cross-sectional view of the magnetoresistance effect element according to the first embodiment.

FIG. 5 is another cross-sectional view of the magnetoresistance effect element according to the first embodiment.

FIG. 6 is a view showing an example of a method of manufacturing the magnetoresistance effect element according to the first embodiment.

FIG. 7 is a view showing an example of the method of manufacturing the magnetoresistance effect element according to the first embodiment.

FIG. 8 is a view showing an example of the method of manufacturing the magnetoresistance effect element according to the first embodiment.

FIG. 9 is a view showing an example of the method of manufacturing the magnetoresistance effect element according to the first embodiment.

FIG. 10 is a cross-sectional view of a magnetoresistance effect element according to a second embodiment.

FIG. 11 is a cross-sectional view of a magnetoresistance effect element according to a third embodiment.

FIG. 12 is a cross-sectional view of a magnetoresistance effect element according to a fourth embodiment.

FIG. 13 is a cross-sectional view of a magnetoresistance effect element according to a fifth embodiment.

FIG. 14 is a cross-sectional view of a magnetoresistance effect element according to a sixth embodiment.

FIG. 15 is another cross-sectional view of the magnetoresistance effect element according to the sixth embodiment.

FIG. 16 is another cross-sectional view of the magnetoresistance effect element according to the sixth embodiment.

FIG. 17 is a view showing an example of a method of manufacturing the magnetoresistance effect element according to the sixth embodiment.

FIG. 18 is a view showing an example of the method of manufacturing the magnetoresistance effect element according to the sixth embodiment.

FIG. 19 is a view showing an example of a method of manufacturing a magnetoresistance effect element according to a seventh embodiment.

FIG. 20 is a cross-sectional view of a magnetoresistance effect element according to a first variant.

FIG. 21 is a cross-sectional view of a magnetoresistance effect element according to a second variant.

### DESCRIPTION OF EMBODIMENTS

Hereinafter, embodiments of the present invention will be described in detail with reference to the accompanying drawings as appropriate. In the drawings used in the following description, in order to make the features easier to understand, the characteristic portions may be enlarged for convenience, and dimensional ratios of components may differ from the actual ones. The materials, dimensions, and the like exemplified in the following description are examples, and the present invention is not limited to them, and it is possible to modify them appropriately within the scope of the effect of the present invention.

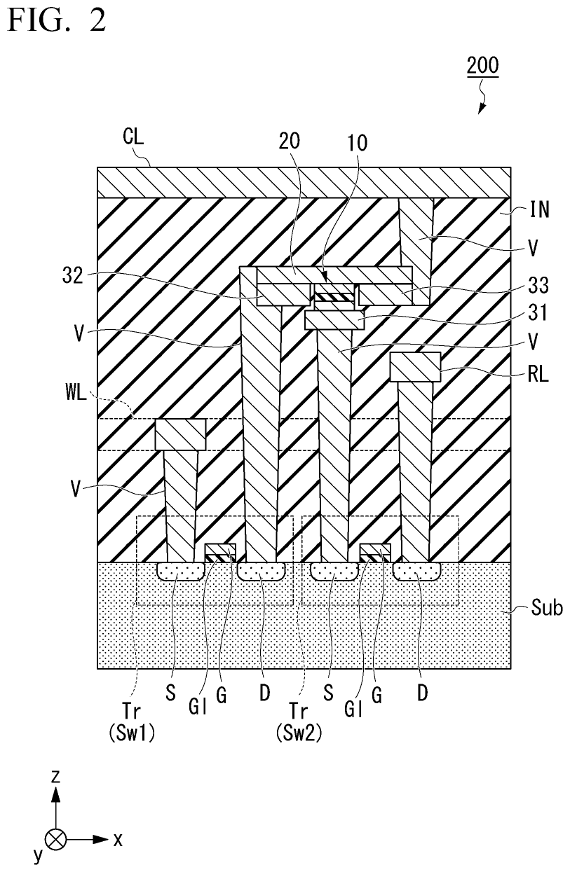

First, the directions will be defined. On one surface of a substrate Sub (see FIG. 2), which will be described below, one direction is referred to as an x direction, and a direction perpendicular to the x direction is referred to as a y direction. The x direction is, for example, a direction from a second electrode 32 toward a third electrode 33. A z direction is a direction perpendicular to the x direction and the y direction. The z direction is an example of a laminating direction in which each layer is laminated. Hereinafter, a +z direction may be expressed as “upward” and a-z direction may be expressed as “downward.” Upward and downward do not necessarily match the direction to which gravity is applied.

“Extending in the x direction” in the specification means that, for example, a dimension in the x direction is greater than a minimum dimension of dimensions in the x direction, the y direction, and the z direction. A case in which it extends in another direction is also the same as above. In addition, “connection” in the specification is not limited to a case of being connected directly and includes a case of being connected indirectly. “Indirect connection” is, for example, a case in which two layers are connected with another layer sandwiched therebetween. “Connection” in the specification includes electrical connection.

### First Embodiment

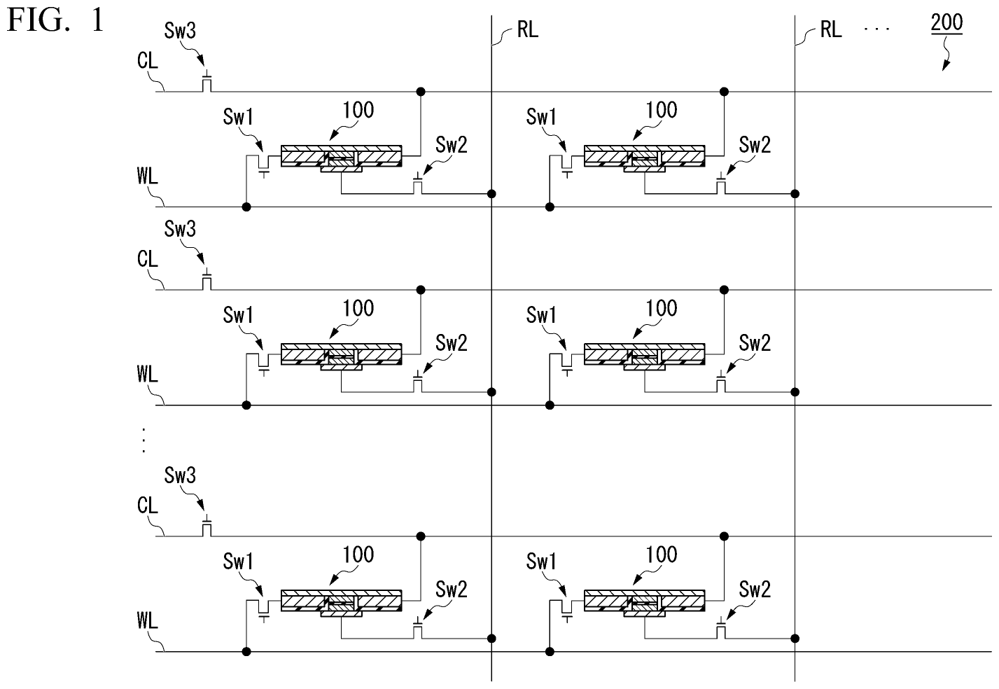

FIG. 1 is a configuration view of a magnetic array 200 according to a first embodiment. The magnetic array 200 includes a plurality of magnetoresistance effect elements 100, a plurality of writing wirings WL, a plurality of common wirings CL, a plurality of reading wirings RL, a plurality of first switching elements Sw1, a plurality of second switching elements Sw2, and a plurality of third switching elements Sw3. The magnetic array 200 can be used in, for example, a magnetic memory or the like.

Each of the writing wirings WL electrically connects a power supply and one or more of the magnetoresistance effect elements 100. Each of the common wirings CL is a wiring used in both upon writing and reading of data. Each of the common wirings CL electrically connects a reference potential and one or more of the magnetoresistance effect elements 100. The reference potential is, for example, the ground. The common wirings CL may be provided on the plurality of magnetoresistance effect elements 100, respectively, or may be provided over the plurality of magnetoresistance effect elements 100. Each of the reading wirings RL electrically connects a power supply and one or more of the magnetoresistance effect elements 100. The power supply is connected to the magnetic array 200 when in use.

Each of the magnetoresistance effect elements 100 is connected to the first switching elements Sw1, the second switching element Sw2, and the third switching element Sw3. The first switching element Sw1 is connected between the magnetoresistance effect elements 100 and the writing wiring WL. The second switching element Sw2 is connected between the magnetoresistance effect elements 100 and the reading wiring RL. The third switching element Sw3 is connected to the common wiring CL over the plurality of magnetoresistance effect elements 100.

When the first switching element Sw1 and the third switching element Sw3 are turned ON, writing current flows between the writing wiring WL and the common wiring CL, which are connected to the predetermined magnetoresistance effect element 100. Data is written on the predetermined magnetoresistance effect element 100 by flowing the writing current. When the second switching element Sw2 and the third switching element Sw3 are turned ON, reading current flows between the common wiring CL and the reading wiring RL, which are connected to the predetermined magnetoresistance effect element 100. Data are read from the predetermined magnetoresistance effect element 100 by flowing the reading current.

The first switching elements Sw1, the second switching elements Sw2 and the third switching elements Sw3 are elements configured to control a flow of current. The first switching elements Sw1, the second switching elements Sw2 and the third switching elements Sw3 are, for example, a transistor, an element using a phase change of a crystalline layer such as an Ovonic threshold switch (OTS), an element using a change of a band structure, such as a metal insulator transition (MIT) switch, an element using a breakdown voltage, such as a Zener diode and an avalanche diode, and an element, a conductivity of which is changed according to a change of an atomic position.

In the magnetic array 200 shown in FIG. 1, the magnetoresistance effect elements 100 connected to the same wiring share the third switching element Sw3. The third switching elements Sw3 may be provided on the magnetoresistance effect elements 100, respectively. In addition, the third switching elements Sw3 may be provided on the magnetoresistance effect elements 100, respectively, and the first switching element Sw1 or the second switching element Sw2 may be shared by the magnetoresistance effect elements 100 connected to the same wiring.

FIG. 2 is a cross-sectional view of a feature portion of the magnetic array 200 according to the first embodiment. FIG. 2 shows a cross section of the magnetoresistance effect element 100 cut along an xz plane passing through a center of a width of a spin orbit torque wiring 20 in the y direction, which will be described below.

The first switching element Sw1 and the second switching element Sw2 shown in FIG. 2 are transistors Tr. The third switching element Sw3 are electrically connected to the common wiring CL, and for example, are located at positions shifted in the x direction of FIG. 2. The transistors Tr are, for example, electric field effect type transistors, and have sources S and drains D formed on the substrate Sub, a gate electrode G and a gate insulating film GI. The sources S and the drains D are defined by a flow direction of the current and are located in the same region. A positional relation between the sources S and the drains D may be inverted. The substrate Sub is, for example, a semiconductor substrate.

The transistors Tr and the magnetoresistance effect element 100 are electrically connected through via wirings V. In addition, the transistors Tr and the writing wiring WL or the reading wiring RL are connected by the via wiring V. The via wirings V extend, for example, in the z direction. The via wirings V include materials having conductivity.

Surroundings of the magnetoresistance effect elements 100 and the transistors Tr are covered with an insulating layer In. The insulating layer In is an insulating layer configured to insulate wirings or elements of a multilayer wiring. The insulating layer In is, for example, silicon oxide (SiOₓ), silicon nitride (SiNₓ), silicon carbide (SiC), chromium nitride, silicon carbonitride (SiCN), silicon oxynitride (SiON), aluminum oxide (Al₂O₃), zirconium oxide (ZrOₓ), magnesium oxide (MgO), aluminum nitride (AlN), or the like.

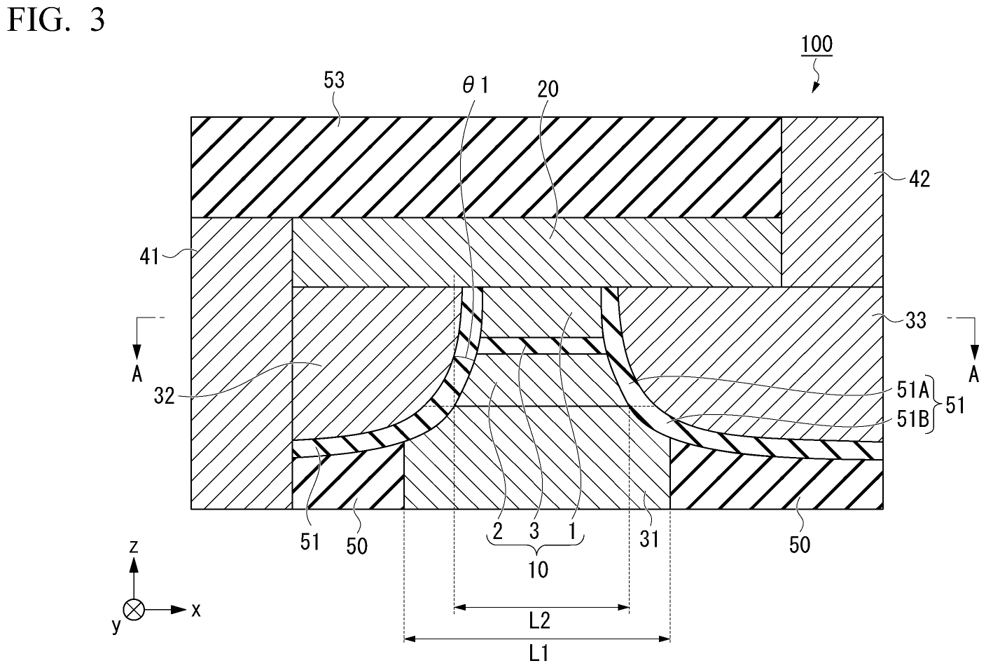

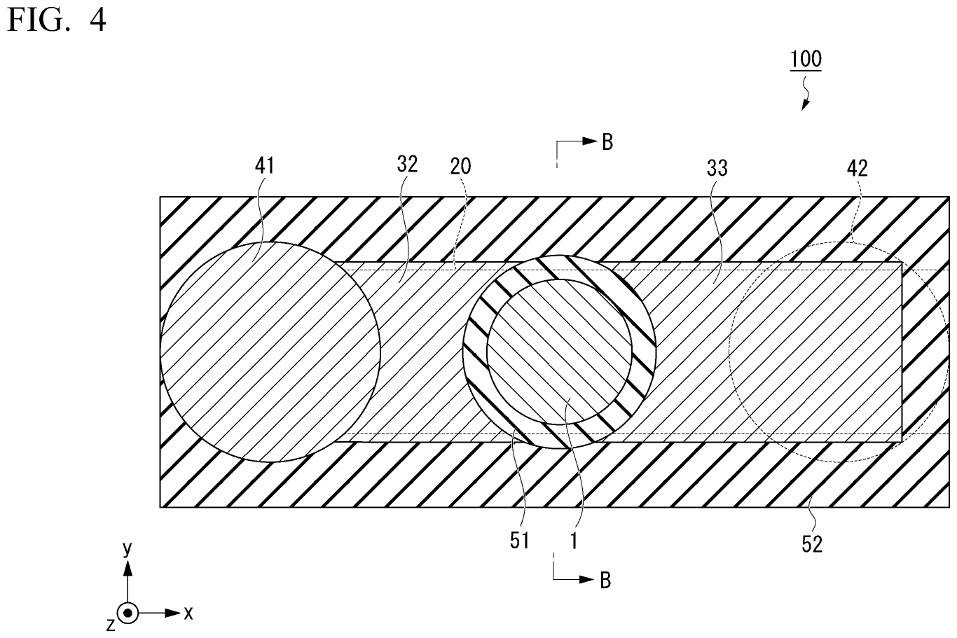

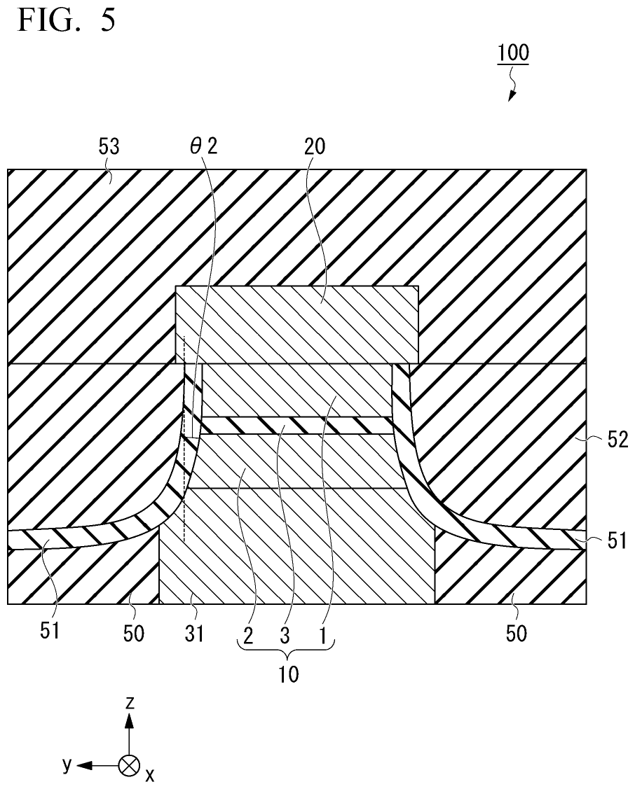

FIG. 3 is a cross-sectional view of the magnetoresistance effect element 100. FIG. 3 is a cross section of the magnetoresistance effect element 100 cut along an xz plane passing through a center of a width of the spin orbit torque wiring 20 in the y direction. FIG. 4 is a cross-sectional view of the magnetoresistance effect element 100 cut along line A-A in FIG. 3. FIG. 5 is a cross section of the magnetoresistance effect element 100 cut along line B-B in FIG. 4.

The magnetoresistance effect element 100 has, for example, a laminated body 10, the spin orbit torque wiring 20, a first electrode 31, the second electrode 32, the third electrode 33, a first via wiring 41, a second via wiring 42, a sidewall insulating layer 51, and insulating layers 50, 52 and 53.

The spin orbit torque wiring 20 is an example of a first wiring. The first via wiring 41 and the second via wiring 42 are part of the via wirings V. The insulating layers 50, 52 and 53 are part of the insulating layer ln. The insulating layer 50 covers surroundings of the first electrode 31. The insulating layer 52 is a side of the laminated body 10 in the y direction. The insulating layer 53 covers surroundings of the spin orbit torque wiring 20.

A resistance value of the laminated body 10 in the z direction is changed as spins are injected into the laminated body 10 from the spin orbit torque wiring 20. The magnetoresistance effect element 100 is a magnetic element using a spin orbit torque (SOT), and may be referred to as a spin orbit torque type magnetoresistance effect element, a spin injection type magnetoresistance effect element, or a spin current magnetoresistance effect element.

The laminated body 10 is sandwiched between the spin orbit torque wiring 20 and the first electrode 31 in the z direction. The laminated body 10 is a columnar body. A shape of the laminated body 10 when seen in a plan view in the z direction is, for example, a circular shape, an elliptical shape, or a quadrangular shape.

A side surface of the laminated body 10 is inclined with respect to, for example, the z direction. An inclination angle θ1 of a first cut section (FIG. 3) of the laminated body 10 cut along the xz plane with respect to the z direction of the side surface of the laminated body 10 is greater than, for example, an inclination angle θ2 of a second cut section (FIG. 5) of the laminated body 10 cut along the yz plane with respect to the z direction of the side surface of the laminated body 10. The inclination angles θ1 and θ2 are inclination angles of the side surfaces of the laminated body 10 in the first surface of the laminated body 10 on the side of the first electrode 31.

When the inclination angle θ2 is small, a width of the magnetoresistance effect element 100 in the y direction is reduced. When the inclination angle θ2 is small, a large number of magnetoresistance effect elements 100 can be integrated within the same area. The width of the magnetoresistance effect element 100 in the y direction is smaller than the width in the x direction as an example. In this case, the width of the magnetoresistance effect element 100 in the y direction has a greater influence on the integration of the magnetic array 200 than the width in the x direction.

The laminated body 10 has, for example, a first ferromagnetic layer 1, a second ferromagnetic layer 2, and a nonmagnetic layer 3. The laminated body 10 is obtained by laminating the second ferromagnetic layer 2, the nonmagnetic layer 3 and the first ferromagnetic layer 1 in sequence from a side close to the substrate Sub.

The first ferromagnetic layer 1 is in contact with, for example, the spin orbit torque wiring 20. Spins are injected into the first ferromagnetic layer 1 from the spin orbit torque wiring 20. Magnetization of the first ferromagnetic layer 1 receives the spin orbit torque (SOT) due to the injected spins, and the orientation direction changes. The second ferromagnetic layer 2 is located on the first electrode 31. The first ferromagnetic layer 1 and the second ferromagnetic layer 2 sandwich the nonmagnetic layer 3 in the z direction.

The first ferromagnetic layer 1 and the second ferromagnetic layer 2 have magnetizations, respectively. The orientation direction of the magnetization of the second ferromagnetic layer 2 is less likely to change than the magnetization of the first ferromagnetic layer 1 when a predetermined external force is applied. The first ferromagnetic layer 1 may be referred to as a magnetization free layer, and the second ferromagnetic layer 2 may be referred to as a magnetization fixing layer or a magnetization reference layer. The laminated body 10 shown in FIG. 3 has a magnetization fixing layer on the side of the substrate Sub, and is referred to as a bottom pin structure. The laminated body 10 has a resistance value that is changed according to a difference in relative angle of the magnetizations of the first ferromagnetic layer 1 and the second ferromagnetic layer 2 hat sandwich the nonmagnetic layer 3.

The first ferromagnetic layer 1 and the second ferromagnetic layer 2 include ferromagnetic materials. The ferromagnetic materials are, for example, a metal selected from the group consisting of Cr, Mn, Co, Fe and Ni, an alloy containing one or more of these metals, an alloy containing at least one or more of these metals, B, C, and N, and the like. The ferromagnetic materials are for example, Co—Fe, Co—Fe—B, Ni—Fe, a Co—Ho alloy, a Sm—Fe alloy, a Fe—Pt alloy, a Co—Pt alloy, a CoCrPt alloy, and the like.

The first ferromagnetic layer 1 and the second ferromagnetic layer 2 may contain a heusler alloy. The heusler alloy contains intermetallic compound having a chemical composition of XYZ or X₂YZ. X is a transition metal element or a precious metal element of Co, Fe, Ni, or Cu group on a periodic table, Y is a transition metal of Mn, V, Cr or Ti group or an element species of X, and Z is a typical element of a III group to a V group. The heusler alloy is, for example, Co₂FeSi, Co₂FeGe, Co₂FeGa, Co₂MnSi, Co₂Mn₁₋ₐFeₐAl_{b}Si_{1-b}, Co₂FeGe_{1-c}Ga_{c}, or the like. The heusler alloy has high spin polarizability.

The nonmagnetic layer 3 includes a non-magnetic body. When the nonmagnetic layer 3 is the insulating material (a tunnel barrier layer), for example, Al₂O₃, SiO₂, MgO, MgAl₂O₄, and the like, can be used as the material. In addition, in addition to these, a material or the like in which some of Al, Si, Mg is substituted with Zn, Be, or the like, can also be used. Among these materials, since MgO or MgAl₂O₄ is a material that can realize a coherent tunnel, the spins can be efficiently injected. When the nonmagnetic layer 3 is a metal, Cu, Au, Ag, or the like, can be used as the material. Further, when the nonmagnetic layer 3 is a semiconductor, Si, Ge, CuInSe₂, CuGaSe₂, Cu(In, Ga)Se₂, or the like, can be used as the material.

The laminated body 10 may have other layers than the first ferromagnetic layer 1, the second ferromagnetic layer 2 and the nonmagnetic layer 3. For example, a base layer may be provided between the first electrode 31 and the second ferromagnetic layer 2. The base layer increases crystallinity of each layer that constitutes the laminated body 10. In addition, for example, a cap layer may be provided on the uppermost surface of the laminated body 10.

The second ferromagnetic layer 2 may be a synthetic anti-ferromagnetic structure (SAF structure) constituted by two magnetic layers that sandwich a spacer layer. Since the two ferromagnetic layers are anti-ferromagnetically coupled, a coercive force of the second ferromagnetic layer 2 is increased. The spacer layer includes at least one selected from the group consisting of, for example, Ru, Ir, and Rh.

The spin orbit torque wiring 20 connects the second electrode 32 and the third electrode 33. The writing current flows in the x direction of the spin orbit torque wiring 20. The spin orbit torque wiring 20 is located on the laminated body 10.

The spin orbit torque wiring 20 generates a spin current due to a spin Hall effect when a current flows, and injects spins into the first ferromagnetic layer 1. For example, the spin orbit torque wiring 20 applies the spin orbit torque (SOT) that can sufficiently invert the magnetization of the first ferromagnetic layer 1 to the magnetization of the first ferromagnetic layer 1. The spin Hall effect is a phenomenon in which the spin current is induced in a direction perpendicular to the direction in which the current flows based on the spin-orbit interaction when the current flows. The spin Hall effect is common with a normal Hall effect in that moving (shifting) electric charges (electrons) are curve in a moving (shifting) direction. In the normal Hall effect, the moving direction of the charged particles moving in the magnetic field is curved by the Lorentz force. On the other hand, in the spin Hall effect, even when the magnetic field is not present, the shifting direction of the spins can be curve just by shifting electrons (just by flowing current).

For example, when the current flows through the spin orbit torque wiring 20, a first spin oriented in one direction and a second spin oriented in a direction opposite to the first spin are bent by the spin Hall effect in a direction perpendicular to the direction in which each current flows. For example, the first spin oriented in the −y direction is curved in the +z direction, and the second spin oriented in the +y direction is curved in the −z direction.

In the non-magnetic body (a material that is not a ferromagnetic material), the number of electrons of the first spin generated by the spin Hall effect is equal to the number of electrons of the second spin. That is, the number of electrons of the first spin in the +z direction is equal to the number of electrons of the second spin in the −z direction. The first spin and the second spin flow in a direction in which uneven distribution of the spins is eliminated. In shifting of the first spin and the second spin in the z direction, since the flows of the electric charges cancel each other, the amount of current becomes zero. The spin current with no current is specifically referred to as a pure spin current.

Provided that a flow of the electrons of the first spin is expressed as J_{⬆}, a flow of the electrons of the second spin is expressed as J_{⬇}, and a spin current is expressed as J_{S}, they are defined as J_{S}=J_{⬆}−J_{⬇}. The spin current J_{S} is generated in the z direction. The first spin is injected into the first ferromagnetic layer 1 from the spin orbit torque wiring 20.

The spin orbit torque wiring 20 contains any one of a metal, an alloy, intermetallic compound, metal boride, metal carbide, metal silicide, and metal phosphide, which have a function of generating a spin current by a spin Hall effect when current flows.

The spin orbit torque wiring 20 contains, for example, a non-magnetic heavy metal as a main element. The main element is an element with the highest ratio among the elements that constitute the spin orbit torque wiring 20. The spin orbit torque wiring 20 contains a heavy metal having a specific weight more than, for example, yttrium (Y). Since the non-magnetic heavy metals have atomic numbers equal to or greater than atomic number 39 and have d electrons or f electrons in the outermost shell, a spin-orbit interaction occurs strongly. The spin Hall effect is caused by the spin-orbit interaction, the spin tends to be unevenly distributed within the spin orbit torque wiring 20, and the spin current Js tends to occur. The spin orbit torque wiring 20 contains any one selected from the group consisting of, for example, Au, Hf, Mo, Pt, W, and Ta.

The spin orbit torque wiring 20 may contain a magnetic metal. The magnetic metal is a ferromagnetic metal or an anti-ferromagnetic metal. A small amount of magnetic metal contained in a non-magnetic body becomes a scattering factor of spins. The small amount is, for example, 3% or less of the total molar ratio of the elements that constitute the spin orbit torque wiring 20. When the spins are scattered by the magnetic metal, the spin-orbit interaction is enhanced, and the generation efficiency of the spin current to the current becomes higher.

The spin orbit torque wiring 20 may contain a topological insulating material. The topological insulating material is a material whose interior is an insulating material or high resistance body, but whose surface has a spin-polarized metal state. The topological insulating material produces an internal magnetic field through the spin-orbit interaction. The topological insulating material develops a new topological phase due to the effect of the spin-orbit interaction even without an external magnetic field. The topological insulating materials can generate pure spin current with high efficiency due to the strong spin-orbit interaction and breaking of inversion symmetry at edges.

The topological insulating material is, for example, SnTe, Bi_{1.5}Sb_{0.5}Te_{1.7}Se_{1.3}, TlBiSe₂, Bi₂Te₃, (Bi₁₋ₓSbₓ)₂Te₃, or the like. The topological insulating material can generate the spin current with high efficiency.

The first electrode 31 is connected to the laminated body 10 on a side opposite to the spin orbit torque wiring 20. The laminated body 10 is located, for example, on the first electrode 31. The first electrode 31 contains a material with excellent conductivity. The first electrode 31 is formed of, for example, Al or Cu.

A circumference L1 of the first electrode 31 is equal to or greater than a maximum circumference L2 of the laminated body 10. A circumference of the laminated body 10 is maximized, for example, on the side of the first electrode 31. If the lower surface of the laminated body 10 bridges between the first electrode 31 and the insulating layer 50, when a step difference is provided on an interface between the first electrode 31 and the insulating layer 50, a crystalline structure of the laminated body 10 may be distorted. If the laminated body 10 is formed on the upper surface (the first surface) of the first electrode 31 with high flatness, crystallinity of the laminated body 10 is increased.

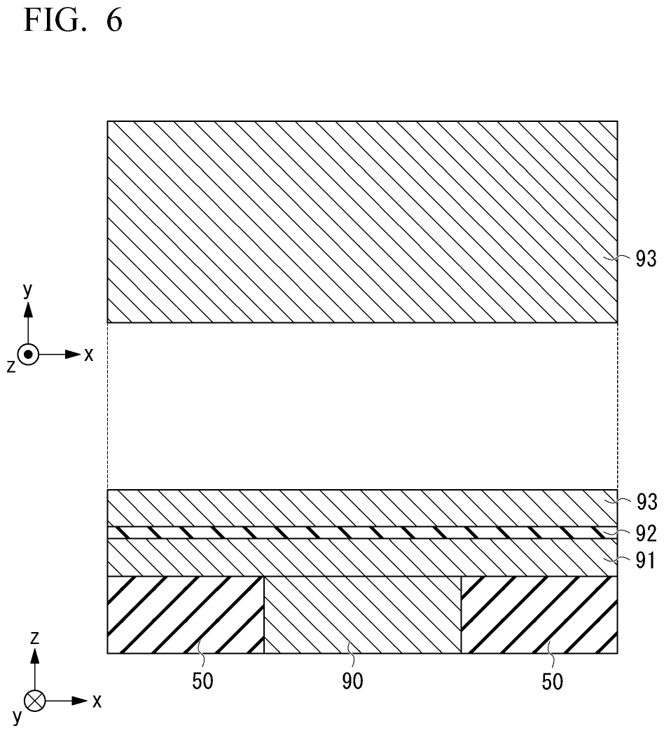

The first electrode 31 has, for example, an inclined surface between the upper surface and the side surface. The inclined surface is formed by cutting out a portion of a metal layer 90 (see FIG. 6) that will become the first electrode 31 during manufacture.

The second electrode 32 and the third electrode 33 are on the sides of the laminated body 10 respectively. The second electrode 32 and the third electrode 33 sandwich the laminated body 10 in the x direction. Each of the second electrode 32 and the third electrode 33 is connected to the spin orbit torque wiring 20.

Each of the second electrode 32 and the third electrode 33 is on the sidewall insulating layer 51. The sidewall insulating layer 51 is provided between the second electrode 32, the laminated body 10 and the first electrode 31. The sidewall insulating layer 51 is provided between the third electrode 33, the laminated body 10 and the first electrode 31. Parts of the second electrode 32 and the third electrode 33 are on sides of the first electrode 31 in the x direction, for example.

The second electrode 32 and the third electrode 33 contain a material with excellent conductivity. The second electrode 32 and the third electrode 33 are formed of, for example, Al or Cu. The second electrode 32 and the third electrode 33 may be formed of the same material as the spin orbit torque wiring 20. For example, the second electrode 32 and the third electrode 33 may contain a metal having a specific weight equal to or greater than that of yttrium as a main component. The heavy metal used for the spin orbit torque wiring 20 is difficult to diffuse and can suppress migration to the first via wiring 41 and the second via wiring 42.

The sidewall insulating layer 51 covers at least a part of the side surface of the laminated body 10. The sidewall insulating layer 51 covers, for example, the entire side surface of the laminated body 10. The sidewall insulating layer 51 covers, for example, surroundings of the laminated body 10. The sidewall insulating layer 51 is provided, for example, between the second electrode 32, the laminated body 10 and the first electrode 31, and between the third electrode 33, the laminated body 10 and the first electrode 31. The sidewall insulating layer 51 insulates the first electrode 31, the second electrode 32 and the third electrode 33 from each other. The sidewall insulating layer 51 is in contact with, for example, the laminated body 10 and the first electrode 31.

The sidewall insulating layer 51 has, for example, a first portion 51A and a second portion 51B. The first portion 51A is a portion in contact with the side surface of the laminated body 10. The second portion 51B is a portion in contact with the first electrode 31. The second portion 51B is in contact with, for example, the inclined surface of the first electrode 31. The second portion 51B is located, for example, below the upper surface of the first electrode 31, and extends downward from the same height position as the upper surface of the first electrode 31.

Each of the first portion 51A and the second portion 51B is inclined with respect to the z direction and the xy plane. An inclination angle of a tangential plane in contact with the sidewall insulating layer 51 with respect to the z direction changes continuously between the first portion 51A and the second portion 51B.

The sidewall insulating layer 51 contains the same material as the insulating layer In. An average thickness of the sidewall insulating layer 51 is greater than, for example, an average thickness of the nonmagnetic layer 3. When the thickness of the sidewall insulating layer 51 is sufficiently great, a short circuit between the first electrode 31, the second electrode 32 and the third electrode 33 can be prevented.

The first via wiring 41 and the second via wiring 42 extend in the z direction. The first via wiring 41 is connected to the second electrode 32. The first via wiring 41 may be connected to the second electrode 32 via the spin orbit torque wiring 20. The second via wiring 42 is connected to the third electrode 33. The second via wiring 42 may be connected to the third electrode 33 via the spin orbit torque wiring 20.

The first via wiring 41 extends, for example, downward from the second electrode 32. The second via wiring 42 extends, upward from the third electrode 33. For example, each of the first via wiring 41 and the second via wiring 42 extends in a direction different from the z direction with reference to the laminated body 10.

The first via wiring 41 and the second via wiring 42 are formed of a material with excellent conductivity. The first via wiring 41 and the second via wiring 42 are formed of, for example, Al, Cu or Ag.

Next, a method of manufacturing the magnetoresistance effect element 100 will be described. The magnetoresistance effect element 100 is formed by a laminating process of each layer, and a processing process of processing a part of each layer in a predetermined shape. Lamination of each layer can use a sputtering method, a chemical vapor deposition (CVD) method, an electron beam deposition method (EB vaporization method), an atom laser deposition method, or the like. Processing of each layer can be performed by using photolithography or the like.

As shown in FIG. 6, a ferromagnetic layer 91, a nonmagnetic layer 92, and a ferromagnetic layer 93 are laminated sequentially on the metal layer 90 and the insulating layer 50.

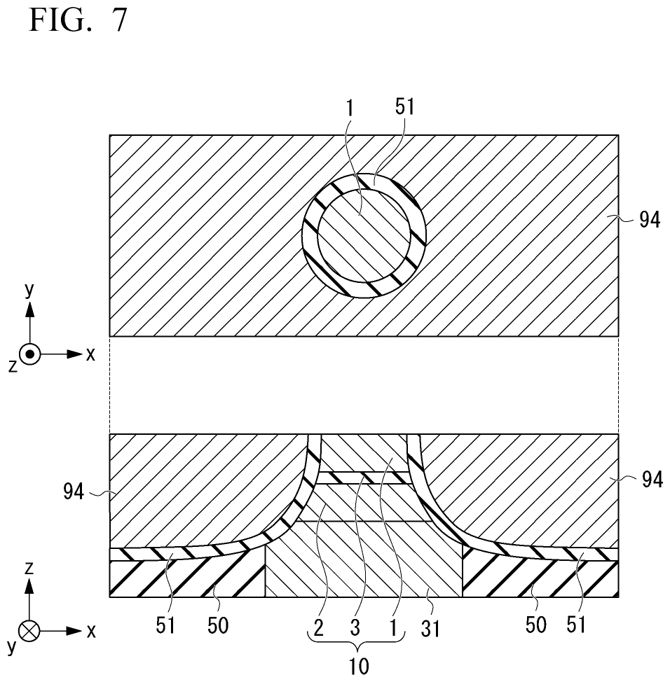

Next, as shown in FIG. 7, unnecessary portions of the ferromagnetic layer 91, the nonmagnetic layer 92 and the ferromagnetic layer 93 are removed. The ferromagnetic layer 91, the nonmagnetic layer 92, and the ferromagnetic layer 93 leave, for example, portions that overlap with the metal layer 90 in the z direction. Removal of the unnecessary portions is performed by, for example, etching via a mask. An upper portion of the metal layer 90 is cut out, and the metal layer 90 becomes the first electrode 31. The ferromagnetic layer 91 becomes the second ferromagnetic layer 2, the nonmagnetic layer 92 becomes the nonmagnetic layer 3, and the ferromagnetic layer 93 becomes the first ferromagnetic layer 1.

Next, the sidewall insulating layer 51 and a metal layer 94 are laminated in sequence on the insulating layer 50, the first electrode 31 and the laminated body 10. Then, parts of the sidewall insulating layer 51 and the metal layer 94, which are laminated, are removed until the upper surface of the first ferromagnetic layer 1 is exposed.

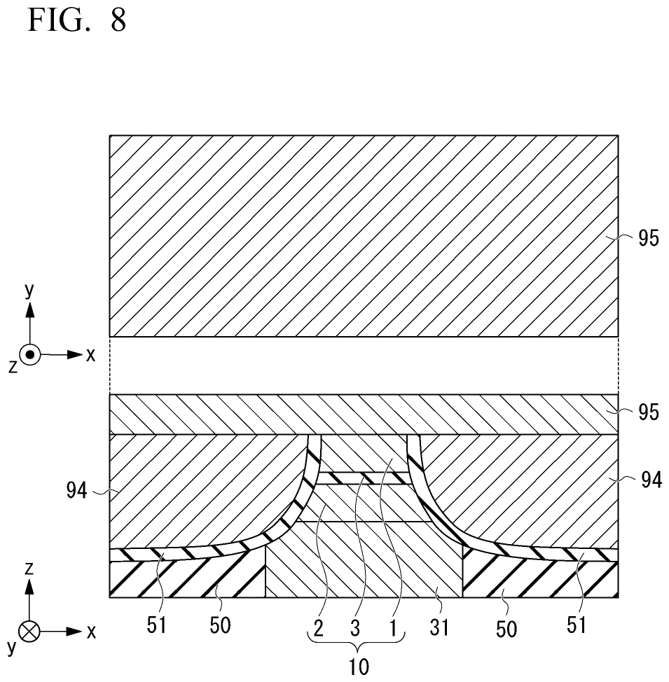

Next, as shown in FIG. 8, a metal layer 95 is formed on the first ferromagnetic layer 1, the sidewall insulating layer 51 and the metal layer 94.

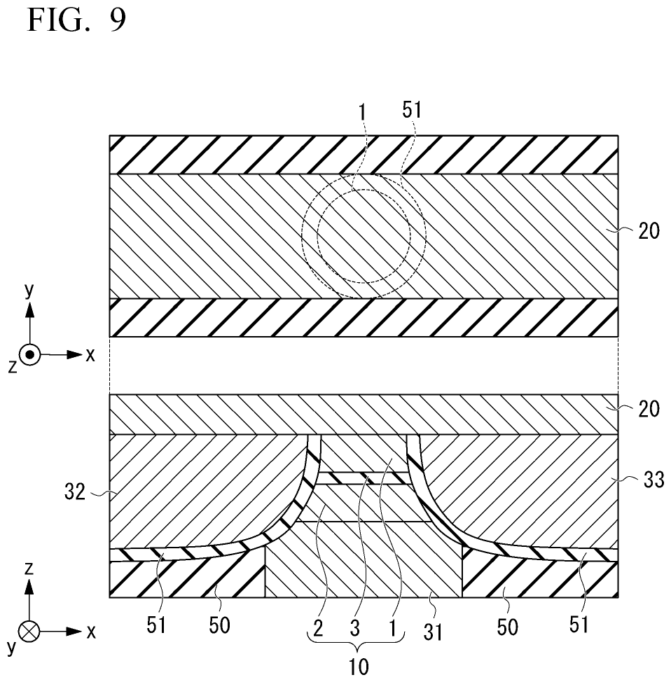

Next, as shown in FIG. 9, the metal layers 94 and 95 are processed in the y direction, and the unnecessary portions are removed. The metal layer 94 becomes the second electrode 32 and the third electrode 33. The metal layer 95 becomes the spin orbit torque wiring 20. After that, openings extending in the z direction are formed at positions overlapping the second electrode 32 and the third electrode 33, respectively, and filled with conductors. The conductors with which the openings are filled become the first via wiring 41 and the second via wiring 42. The magnetoresistance effect element 100 is obtained in such a sequence.

In the magnetoresistance effect element 100 according to the first embodiment, the length of the spin orbit torque wiring 20 in the x direction can be defined by the thickness of the sidewall insulating layer 51, and does not depend on processing process accuracy. For this reason, the length of the spin orbit torque wiring 20 in the x direction can be reduced, and malfunction according to heat generation of the spin orbit torque wiring 20 can be suppressed.

In addition, the second electrode 32 and the third electrode 33 can be easily fabricated by cutting the metal layer 95, which was formed.

### Second Embodiment

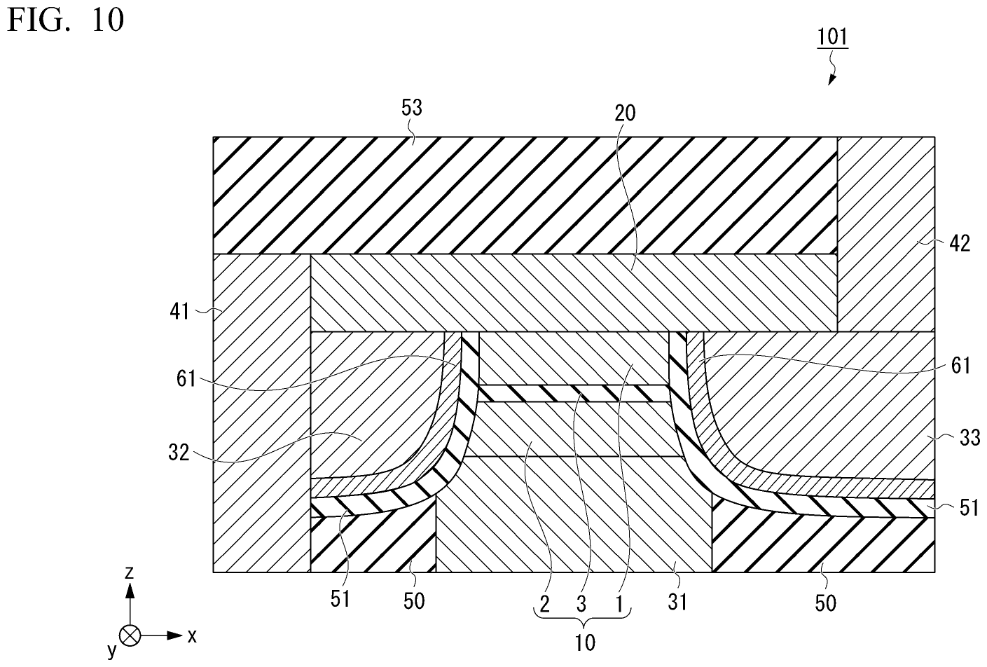

FIG. 10 is a cross-sectional view of a magnetoresistance effect element 101 according to a second embodiment. FIG. 10 shows a cross section of the magnetoresistance effect element 101 cut along the xz plane passing through a center of the width of the spin orbit torque wiring 20 in the y direction. The magnetoresistance effect element 101 according to the second embodiment is distinguished from the magnetoresistance effect element 100 according to the first embodiment in that a diffusion prevention layer 61 is provided. In the second embodiment, the same reference signs designate the same components as in the first embodiment.

The diffusion prevention layer 61 is provided between at least one of the second electrode 32 and the third electrode 33, and the sidewall insulating layer 51. The diffusion prevention layer 61 suppresses the element that constitutes the second electrode 32 and the third electrode 33 from being diffused to another layer. For example, the diffusion prevention layer 61 prevents the metal element that constitutes the second electrode 32 or the third electrode 33 from being diffused to the sidewall insulating layer 51. When the metal element is diffused to the sidewall insulating layer 51, the first electrode 31 and the second electrode 32 or the third electrode 33 are easily short-circuited.

The diffusion prevention layer 61 contains, for example, the same material as the spin orbit torque wiring 20. The diffusion prevention layer 61 contains, for example, a metal having a specific weight equal to or greater than that of yttrium as a main component.

In the magnetoresistance effect element 101 according to the second embodiment, the same effects as in the magnetoresistance effect element 100 according to the first embodiment are obtained. In addition, migration from the second electrode 32 or the third electrode 33 to another layer can be suppressed by the diffusion prevention layer 61.

### Third Embodiment

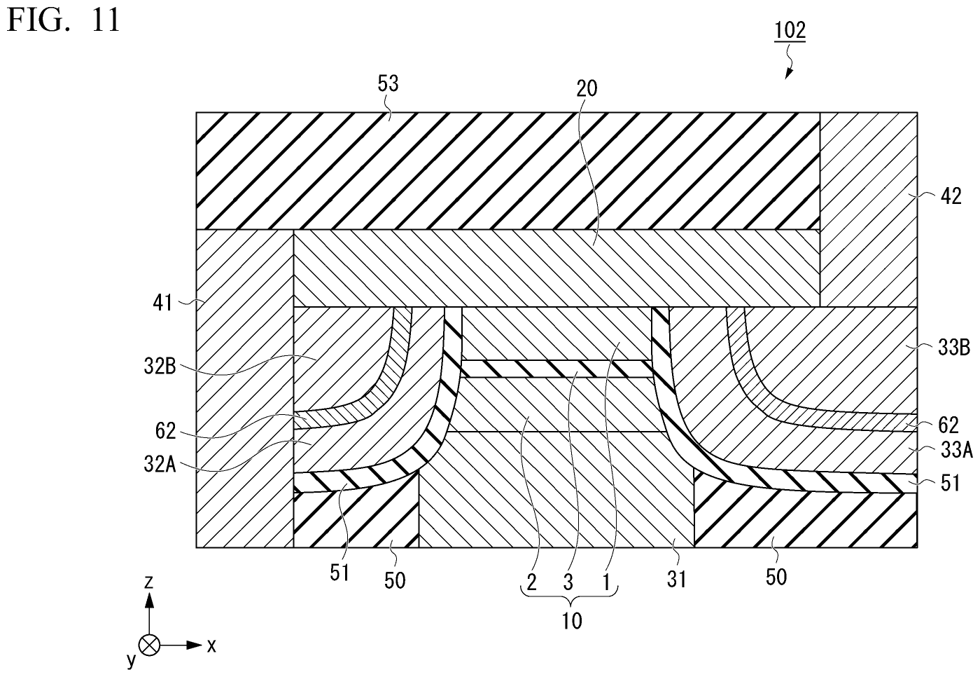

FIG. 11 is a cross-sectional view of a magnetoresistance effect element 102 according to a third embodiment. FIG. 11 shows a cross section of the magnetoresistance effect element 102 cut along an xz plane passing through a center of a width of the spin orbit torque wiring 20 in the y direction. The magnetoresistance effect element 102 according to the third embodiment is distinguished from the magnetoresistance effect element 100 according to the first embodiment in that a diffusion prevention layer 62 is provided. In the third embodiment, the same reference signs designate the same components as in the first embodiment.

The diffusion prevention layer 62 is within at least one of the second electrode 32 and the third electrode 33. The second electrode 32 is divided into a first region 32A and a second region 32B by the diffusion prevention layer 62. In addition, the third electrode 33 is divided into a first region 33A and a second region 33B by the diffusion prevention layer 62.

The diffusion prevention layer 62 contains the same material as the diffusion prevention layer 61. The diffusion prevention layer 62 suppresses the element that constitutes the second electrode 32 and the third electrode 33 from being diffused to another layer.

The magnetoresistance effect element 102 according to the third embodiment exhibits the same effects as in the magnetoresistance effect element 100 according to the first embodiment. In addition, migration from the second electrode 32 or the third electrode 33 to another layer can be suppressed by the diffusion prevention layer 62.

### Fourth Embodiment

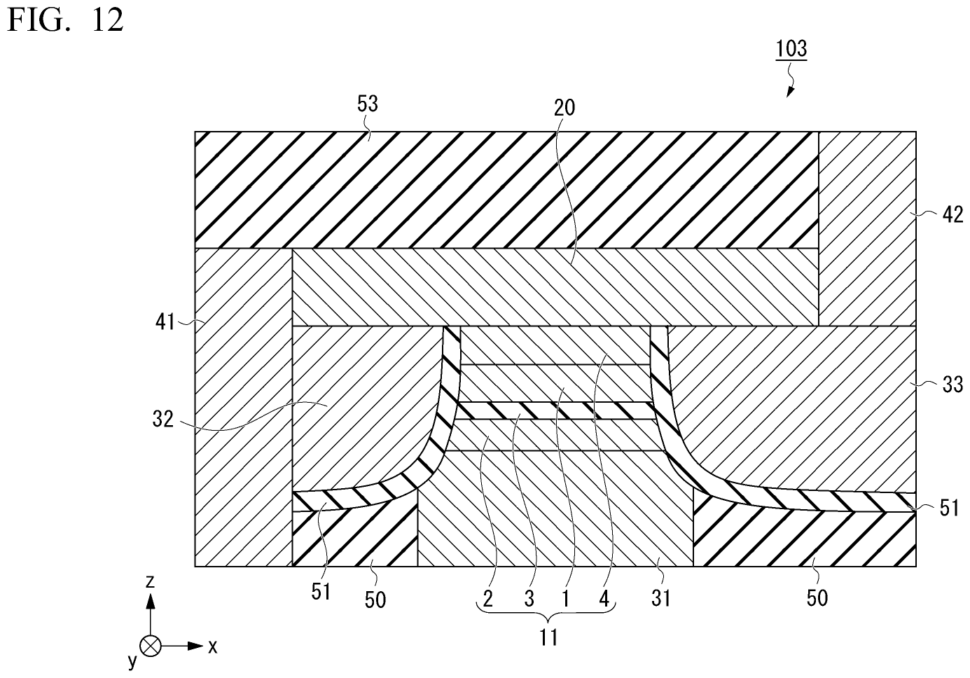

FIG. 12 is a cross-sectional view of a magnetoresistance effect element 103 according to a fourth embodiment. FIG. 12 shows a cross section of the magnetoresistance effect element 103 cut along an xz plane passing through a center of a width of the spin orbit torque wiring 20 in the y direction. The magnetoresistance effect element 103 according to the fourth embodiment is distinguished from the magnetoresistance effect element 100 according to the first embodiment in the configuration of a laminated body 11. In the fourth embodiment, the same reference signs designate the same components as in the first embodiment. The laminated body 11 has the first ferromagnetic layer 1, the second ferromagnetic layer 2, the nonmagnetic layer 3, and a spin generation layer 4. The laminated body 11 is distinguished from the laminated body 10 in that the spin generation layer 4 is provided. The spin generation layer 4 is located on the first ferromagnetic layer 1. The spin generation layer 4 is in contact with the spin orbit torque wiring 20.

The spin generation layer 4 contains, for example, a metal having a specific weight equal to or greater than that of yttrium as a main component. The spin generation layer 4 contains any one element selected from the group consisting of, for example, Mo, Ru, Rh, Pd, Ta, W, Ir, Pt, Au, and Bi. The spin generation layer 4 is any one of a metal, an alloy, intermetallic compound, metal boride, metal carbide, metal silicide, and metal phosphide of any one element selected from the consisting of, for example, Mo, Ru, Rh, Pd, Ta, W, Ir, Pt, Au, and Bi.

Some of the current flowing through the spin orbit torque wiring 20 also flows through the spin generation layer 4, so that the amount of spins injected into the first ferromagnetic layer 1 can be increased.

The spin generation layer 4 is in contact with the sidewall insulating layer 51. When the sidewall insulating layer 51 is oxide, a spin orbit torque is also generated in an interface between the spin generation layer 4 and the sidewall insulating layer 51.

The magnetoresistance effect element 103 according to the fourth embodiment exhibits the same effects as in the magnetoresistance effect element 100 according to the first embodiment. In addition, the amount of spins injected into the first ferromagnetic layer 1 can be increased by providing the spin generation layer 4.

### Fifth Embodiment

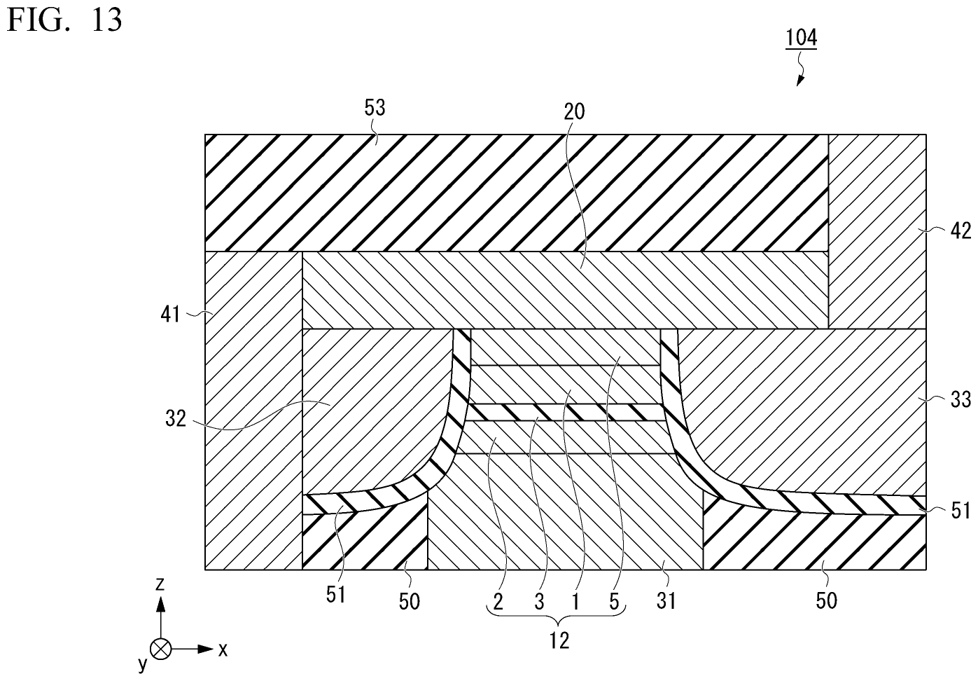

FIG. 13 is a cross-sectional view of a magnetoresistance effect element 104 according to a fifth embodiment. FIG. 13 shows a cross section of the magnetoresistance effect element 104 cut along an xz plane passing through a center of a width of the spin orbit torque wiring 20 in the y direction. The magnetoresistance effect element 104 according to the fifth embodiment is distinguished from the magnetoresistance effect element 100 according to the first embodiment in a configuration of a laminated body 12. In the fifth embodiment, the same reference signs designate the same components as in the first embodiment.

The laminated body 12 has the first ferromagnetic layer 1, the second ferromagnetic layer 2, the nonmagnetic layer 3, and a spin conduction layer 5. The laminated body 12 is distinguished from the laminated body 10 in that the spin conduction layer 5 is provided. The spin conduction layer 5 is located on the first ferromagnetic layer 1. The spin conduction layer 5 is in contact with the spin orbit torque wiring 20.

The spin conduction layer 5 is formed of a metal or a semiconductor containing any one element selected from the group consisting of, for example, Cu, Ag, Al, Mg, Zn, Si, Ge, and C. The spin conduction layer 5 is constituted by a material with a large spin diffusion length and a large spin transport length. The spin diffusion length is a distance for the spin injected into the spin conduction layer 5 to diffuse and information of the injected spin to be halved. The spin transport length is a distance until the spin current of the spin polarization current flowing through the non-magnetic body is halved. When the applied voltage to the spin conduction layer 5 is small, the spin diffusion length and the spin transport length substantially coincide with each other. Meanwhile, when the applied voltage to the spin conduction layer 5 is increased, the spin transport length due to the drift effect is greater than the spin diffusion length.

The spin conduction layer 5 is in contact with the sidewall insulating layer 51. When the sidewall insulating layer 51 is oxide, a spin orbit torque is generated in an interface between the spin conduction layer 5 and the sidewall insulating layer 51.

The magnetoresistance effect element 104 according to the fifth embodiment exhibits the same effects as in the magnetoresistance effect element 100 according to the first embodiment. In addition, by providing the spin conduction layer 5, the spin conduction layer 5 functions as a cap layer, and crystallinity of the laminated body 12 is increased.

### Sixth Embodiment

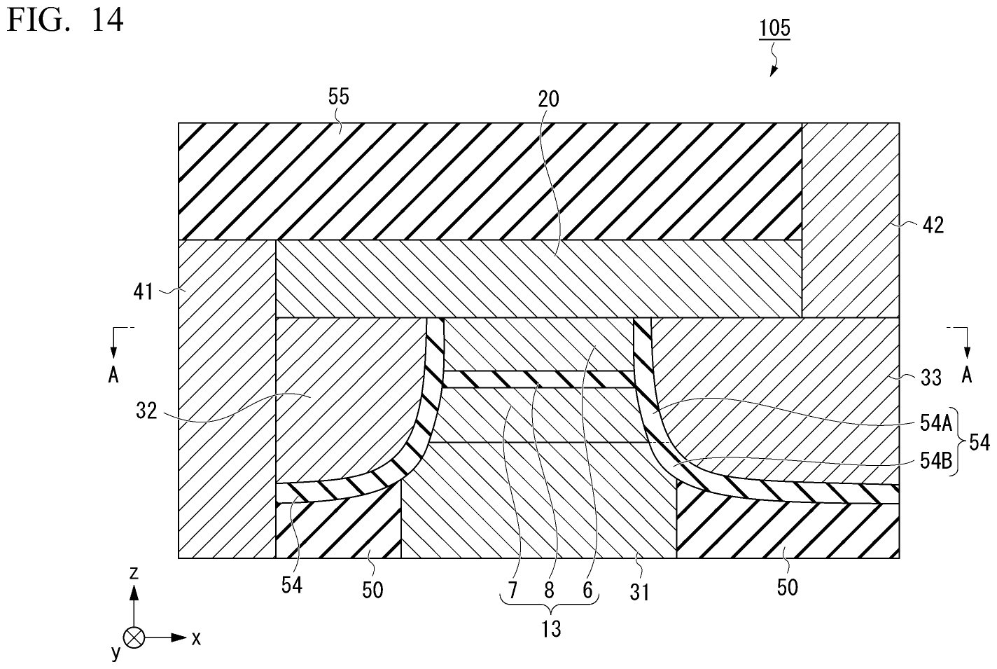

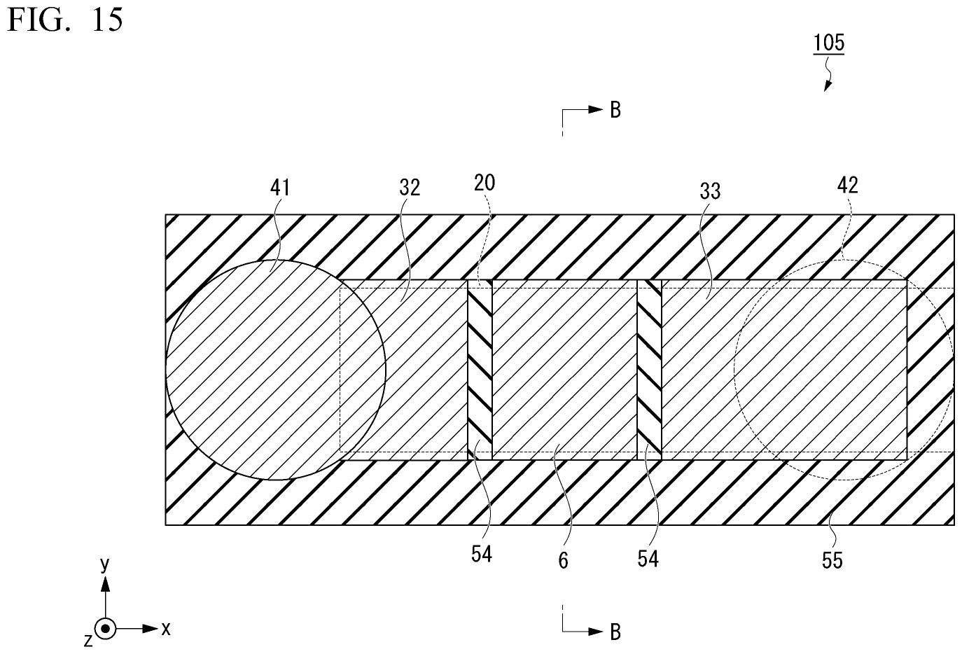

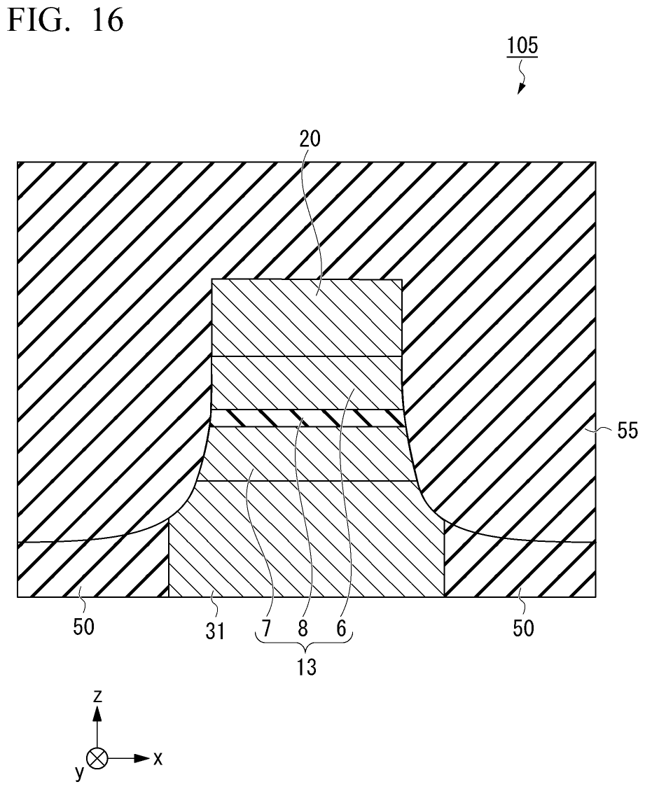

FIG. 14 is a cross-sectional view of a magnetoresistance effect element 105 according to a sixth embodiment. FIG. 14 shows a cross section of the magnetoresistance effect element 105 cut along an xz plane passing through a center of a width of the spin orbit torque wiring 20 in the y direction. FIG. 15 is a cross-sectional view of the magnetoresistance effect element 105 cut along line A-A in FIG. 14. FIG. 16 shows a cross section of the magnetoresistance effect element 105 cut along line B-B in FIG. 15.

The magnetoresistance effect element 105 according to the sixth embodiment is distinguished from the magnetoresistance effect element 100 according to the first embodiment in that a laminated body 13, a sidewall insulating layer 54 and an insulating layer 55 are provided. In the sixth embodiment, the same reference signs designate the same components as in the first embodiment.

The laminated body 13 has a rectangular shape when seen in a plan view in the z direction. The laminated body 13 has a first ferromagnetic layer 6, a second ferromagnetic layer 7, and a nonmagnetic layer 8. The first ferromagnetic layer 6, the second ferromagnetic layer 7 and the nonmagnetic layer 8 correspond to the first ferromagnetic layer 1, the second ferromagnetic layer 2 and the nonmagnetic layer 3, and have different shapes when seen in the z direction.

The sidewall insulating layer 54 covers the side surface of the laminated body 13 in the x direction. The sidewall insulating layer 54 does not cover the side surface of the laminated body 13 in the y direction. The sidewall insulating layer 54 has a first portion 54A configured to cover the side surface of the laminated body 13, and a second portion MB in contact with the first electrode 31.

The insulating layer 55 is a part of the insulating layer In. The insulating layer 55 covers surroundings of the side surface and the spin orbit torque wiring 20 of the laminated body 13 in the y direction.

The magnetoresistance effect element 105 according to the sixth embodiment can be fabricated in the following sequence.

First, like FIG. 6, the ferromagnetic layer 91, the nonmagnetic layer 92, and the ferromagnetic layer 93 are laminated in sequence on the metal layer 90 and the insulating layer 50.

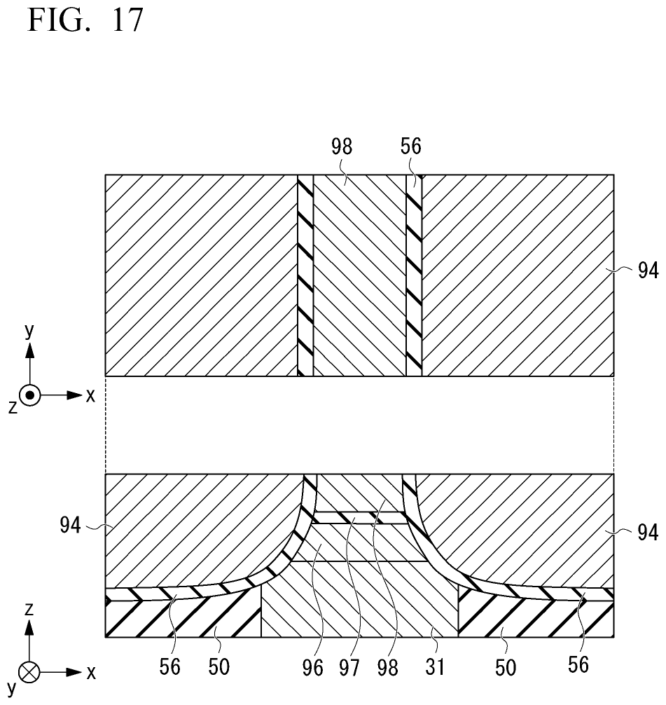

Next, as shown in FIG. 17, unnecessary portions of the ferromagnetic layer 91, the nonmagnetic layer 92 and the ferromagnetic layer 93 in the x direction are removed. The ferromagnetic layer 91, the nonmagnetic layer 92 and the ferromagnetic layer 93 become a ferromagnetic layer 96, a nonmagnetic layer 97 and a ferromagnetic layer 98 extending in the y direction, respectively.

Next, an insulating layer 56 and the metal layer 94 are laminated in sequence on the insulating layer 50, the first electrode 31 and laminated body. Then, parts of the insulating layer 56 and the metal layer 94, which are laminated, are removed until the upper surface of the first ferromagnetic layer 6 is exposed.

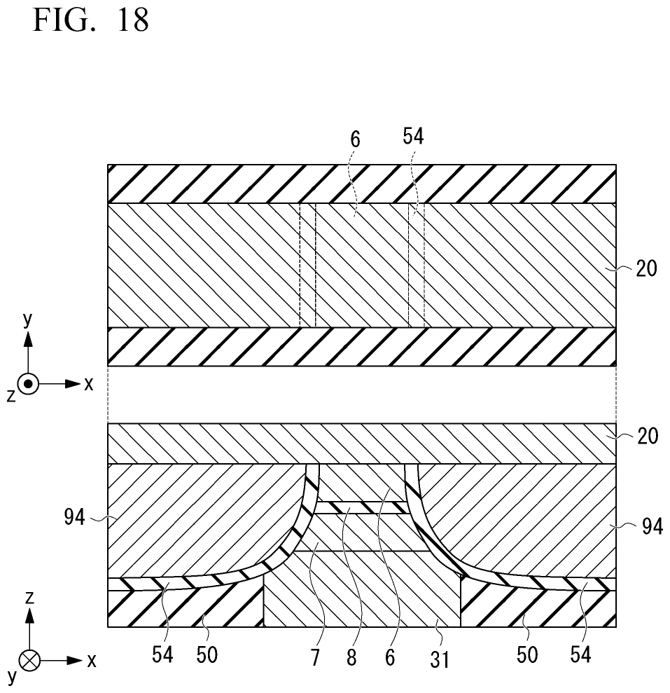

Next, a metal layer is formed on the first ferromagnetic layer 6, the insulating layer 56 and the metal layer 94. Then, as shown in FIG. 18, a lower layer is processed in the y direction and the unnecessary portions are removed while forming the spin orbit torque wiring 20. The ferromagnetic layer 96, the nonmagnetic layer 97 and the ferromagnetic layer 98 become the first ferromagnetic layer 6, the second ferromagnetic layer 7 and the nonmagnetic layer 8. The insulating layer 56 becomes the sidewall insulating layer 54.

The magnetoresistance effect element 105 according to the sixth embodiment exhibits the same effects as in the magnetoresistance effect element 100 according to the first embodiment.

### Seventh Embodiment

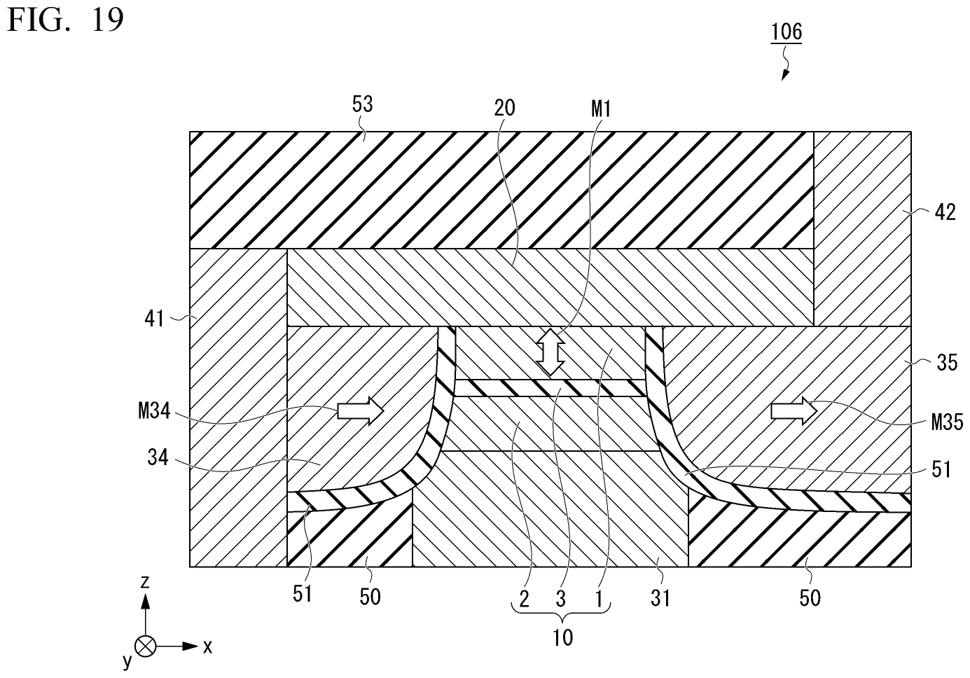

FIG. 19 is a cross-sectional view of a magnetoresistance effect element 106 according to a seventh embodiment. FIG. 19 shows a cross section of the magnetoresistance effect element 106 cut along an xz plane passing through a center of a width of the spin orbit torque wiring 20 in the y direction. The magnetoresistance effect element 106 according to the seventh embodiment is distinguished from the magnetoresistance effect element 100 according to the first embodiment in that a second electrode 34 and a third electrode 35 are magnetic bodies. In the seventh embodiment, the same reference signs designate the same components as in the first embodiment.

The second electrode 34 and the third electrode 35 contain magnetic bodies. The second electrode 34 and the third electrode 35 are formed of, for example, CoCrPt, Fe—Co alloy, heusler alloy, ferrite oxide, or the like.

The second electrode 34 has a magnetization M34. A direction of a magnetization easy axis of the second electrode 34 is, for example, the x direction, and the magnetization M34 is oriented in the x direction. The third electrode 35 has a magnetization M35. A direction of a magnetization easy axis of the third electrode 35 is, for example, the x direction, and the magnetization M35 is oriented in the x direction. The second electrode 34 and the third electrode 35 generate a magnetic field that travels from the second electrode 34 toward the third electrode 35 through the laminated body 10 and back to the second electrode 34. The magnetic field is applied to the laminated body 10 in the x direction.

The direction of the magnetization easy axis of the first ferromagnetic layer 1 and the second ferromagnetic layer 2 is, for example, the z direction.

When the magnetic field in the x direction is applied to the first ferromagnetic layer 1, magnetization inversion of a magnetization M1 becomes easy. This is because the magnetic field produced by the second electrode 34 and the third electrode 35 becomes an external magnetic field and disturbs the inversion symmetry of the magnetization M1 of the first ferromagnetic layer.

The magnetoresistance effect element 106 according to the seventh embodiment exhibits the same effects as in the magnetoresistance effect element 100 according to the first embodiment. In addition, the magnetic field created by the second electrode 34 and the third electrode 35 facilitates the magnetization inversion of the magnetization M1.

Hereinabove, although the example of the magnetoresistance effect element 100 according to the first embodiment is shown, additions, omissions, substitutions, and other changes in configuration are possible without departing from the spirit of the present invention.

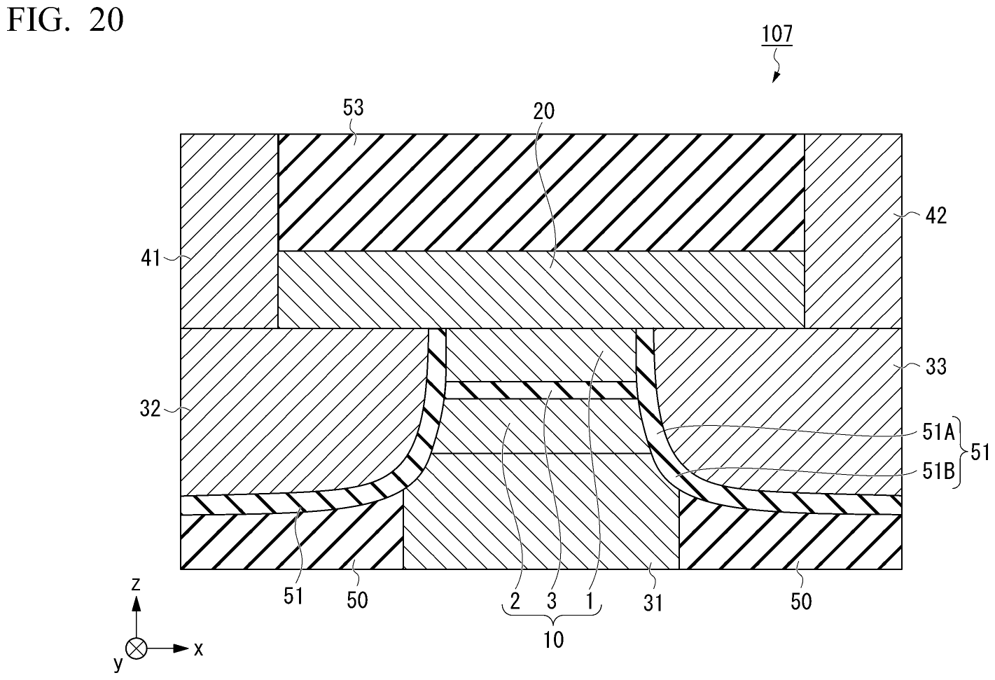

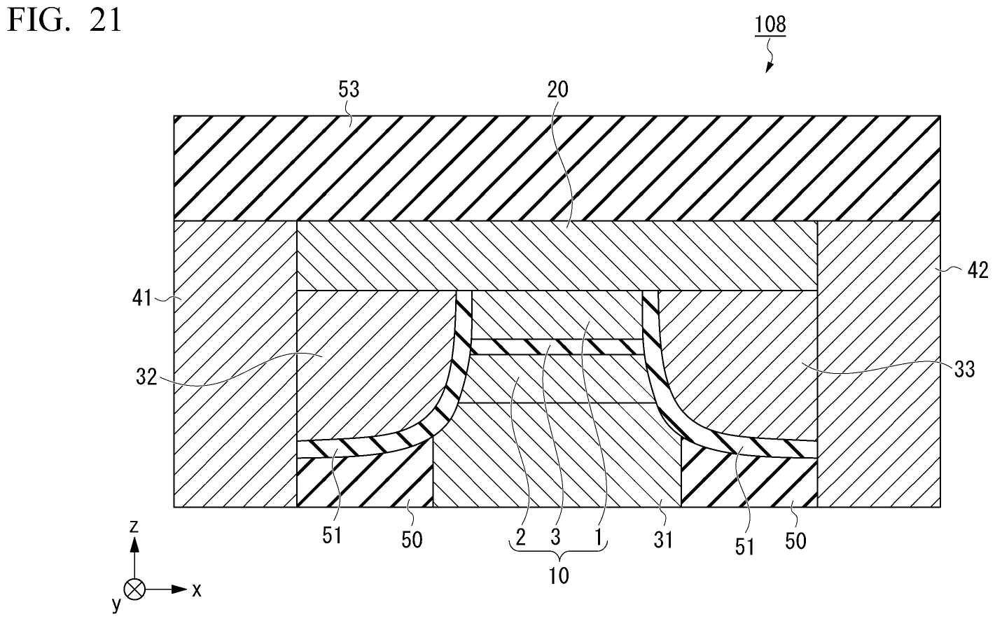

For example, the first via wiring 41 and the second via wiring 42 may not extend in a direction different from the z direction. For example, it may be a first variant shown in FIG. 20 or may be a second variant shown in FIG. 21.

FIG. 20 is a cross-sectional view of a magnetoresistance effect element 107 according to the first variant. In the magnetoresistance effect element 107 according to the first variant, the first via wiring 41 and the second via wiring 42 extend upward from the laminated body 10.

FIG. 21 is a cross-sectional view of a magnetoresistance effect element 108 according to the second variant. In the magnetoresistance effect element 108 according to the second variant, the first via wiring 41 and the second via wiring 42 extend downward from the laminated body 10.

Hereinabove, while the preferred aspects of the present invention have been exemplified based on the embodiments and the variants, the present invention is not limited to these embodiments. For example, the characteristic structures of the embodiments and variants may be applied to other embodiments.

### REFERENCE SIGNS LIST

1, 6 First ferromagnetic layer
2, 7 Second ferromagnetic layer
3, 8 Nonmagnetic layer
4 Spin generation layer
5 Spin conduction layer
10, 11, 12, 13 Laminated body
20 Spin orbit torque wiring
31 First electrode
32, 34 Second electrode
33, 35 Third electrode
41 First via wiring
42 Second via wiring
51, 54 Sidewall insulating layer
51A, 54A First portion
51B, 54B Second portion
61, 62 Diffusion prevention layer
100, 101, 102, 103, 104, 105, 106, 107, 108 Magnetoresistance effect element
200 Magnetic array

What is claimed is:

1. A magnetoresistance effect element comprising:
a laminated body having a first ferromagnetic layer, a second ferromagnetic layer, and a nonmagnetic layer located between the first ferromagnetic layer and the second ferromagnetic layer;
a first wiring connected to the laminated body;
a sidewall insulating layer configured to cover at least a part of a side surface of the laminated body;
a first electrode connected to a side of the laminated body opposite to the first wiring; and
a second electrode and a third electrode provided on both sides of the laminated body with the sidewall insulating layer sandwiched therebetween, sandwiching the laminated body, and connected to the first wiring.

2. The magnetoresistance effect element according to claim 1, wherein the laminated body is located on the first electrode, and
a circumference of the first electrode is equal to or greater than a maximum circumference of the laminated body.

3. The magnetoresistance effect element according to claim 1, wherein the first electrode and the sidewall insulating layer are in contact with each other.

4. The magnetoresistance effect element according to claim 1, wherein the sidewall insulating layer has a first portion in contact with the side surface of the laminated body, and a second portion in contact with the first electrode; and
the first portion and the second portion are inclined with respect to a laminating direction of the laminated body and a surface perpendicular to the laminating direction, respectively.

5. The magnetoresistance effect element according to claim 1, wherein the sidewall insulating layer has a first portion in contact with the side surface of the laminated body, and a second portion in contact with the first electrode; and
an inclination angle of a tangential plane in contact with the sidewall insulating layer with respect to a laminating direction of the laminated body is changed continuously from the first portion to the second portion.

6. The magnetoresistance effect element according to claim 1, wherein the laminated body is located on the first electrode,
the sidewall insulating layer has a first portion in contact with the side surface of the laminated body, and a second portion in contact with the first electrode, and
at least a part of the second portion is located below the first surface of the first electrode on the side of the laminated body.

7. The magnetoresistance effect element according to claim 1, wherein an average thickness of the sidewall insulating layer is greater than an average thickness of the nonmagnetic layer.

8. The magnetoresistance effect element according to claim 1, further comprising a diffusion prevention layer,
wherein the diffusion prevention layer is an inner portion of at least one of the second electrode and the third electrode or between the sidewall insulating layer and the second electrode or the third electrode.

9. The magnetoresistance effect element according to claim 8, wherein the diffusion prevention layer contains a metal having a specific weight equal to or greater than that of yttrium as a main component.

10. The magnetoresistance effect element according to claim 1, wherein at least one of the second electrode and the third electrode contains a metal having a specific weight equal to or greater than yttrium as a main component.

11. The magnetoresistance effect element according to claim 1, wherein the laminated body further includes a spin conduction layer or a spin generation layer connected to the first wiring,
the spin conduction layer is a metal or a semiconductor containing any one element selected from the group consisting of Cu, Ag, Al, Mg, Zn, Si, Ge, and C, and
the spin generation layer contains a metal having a specific weight equal to or greater than that of yttrium as a main component.

12. The magnetoresistance effect element according to claim 11, wherein the sidewall insulating layer is oxide, and the spin conduction layer or the spin generation layer is in contact with the sidewall insulating layer.

13. The magnetoresistance effect element according to claim 1, further comprising a first via wiring connected to the second electrode, and a second via wiring connected to the third electrode.

14. The magnetoresistance effect element according to claim 13, wherein the first via wiring and the second via wiring extend in a direction different from a laminating direction of the laminated body with reference to the laminated body.

15. The magnetoresistance effect element according to claim 1, wherein an inclination angle of a first side surface of the laminated body with respect to the laminating direction at a first cut section cut along a cross section in a first direction from the second electrode toward the third electrode passing through a center when the laminated body is seen in a laminating direction of the laminated body is greater than an inclination angle of a second side surface of the laminated body with respect to the laminating direction in a second cut section passing through the center and perpendicular to the first direction.

16. The magnetoresistance effect element according to claim 1, wherein the second electrode and the third electrode are magnetic bodies having a magnetization easy axis in the first direction from the second electrode toward the third electrode, and
the magnetization easy axis of the first ferromagnetic layer and the second ferromagnetic layer is in the laminating direction of the laminated body.

17. A magnetic memory comprising the plurality of magnetoresistance effect elements according to claim 1.
